(19) United States
(12) Patent Application Publication
(10) Pub. No.: US 2025/0239476 A1
(43) Pub. Date: Jul. 24, 2025

(54) ETCHING METHOD, PRECOAT METHOD, AND ETCHING APPARATUS

(71) Applicant: Tokyo Electron Limited, Tokyo (JP)

(72) Inventors: Takamitsu TAKAYAMA, Miyagi (JP); Yuki ONODERA, Miyagi (JP)

(73) Assignee: Tokyo Electron Limited, Tokyo (JP)

(21) Appl. No.: 19/062,585

(22) Filed: Feb. 25, 2025

Related U.S. Application Data
(63) Continuation of application No. PCT/JP2023/028912, filed on Aug. 8, 2023.

(30) Foreign Application Priority Data
Aug. 26, 2022 (JP) 2022-134827

(51) Int. Cl. H01L 21/683; H01J 37/32; H01L 21/3065

(52) U.S. Cl. CPC H01L 21/6833; H01J 37/32449; H01J 37/32477; H01J 37/32724; H01L 21/3065; H01J 2237/2007; H01J 2237/332; H01J 2237/334

(57) ABSTRACT

An etching method includes (a) forming a carbon-containing film on a surface of an electrostatic chuck in a chamber, (b) disposing a substrate on the carbon-containing film, and (c) etching the substrate with plasma. (a) includes (a1) supplying a precoat gas containing carbon and hydrogen into the chamber and controlling a pressure in the chamber to be 100 mTorr or more and 1,000 mTorr or less, and (a2) generating the plasma from the precoat gas.

### CROSS-REFERENCE TO RELATED APPLICATIONS

This application is a Continuation of International Patent Application No. PCT/JP2023/028912, filed on Aug. 8, 2023, which claims priority from Japanese Patent Application No. 2022-134827, filed on Aug. 26, 2022, with the Japan Patent Office, all of which are incorporated herein in their entireties by reference.

### TECHNICAL FIELD

The present disclosure relates to an etching method, a precoat method, and an etching apparatus.

### BACKGROUND

U.S. Pat. No. 5,952,060 discloses a method of forming a carbon-based coating on a component in a processing chamber. As described therein, the carbon-based coating is a diamond coating or a diamond-like carbon coating, and the method includes supplying a hydrocarbon gas into the processing chamber, generating plasma from the hydrocarbon gas to form the carbon-based coating, degassing the hydrocarbon gas, and then performing a conventional process including etching the substrate. Further, it is described that the method may be performed in situ.

### SUMMARY

According to an aspect of the present disclosure, an etching method includes (a) forming a carbon-containing film on a surface of an electrostatic chuck disposed in a chamber, (b) disposing a substrate on the carbon-containing film, and (c) etching the substrate with plasma. (a) includes (a1) supplying a precoat gas containing carbon and hydrogen into the chamber and controlling a pressure in the chamber to be 100 mTorr or more and 1,000 mTorr or less, and (a2) generating the plasma from the precoat gas.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is an explanatory diagram illustrating a configuration example of a plasma processing system according to an embodiment.

FIG. 2 is a cross-sectional view illustrating a configuration example of a plasma processing apparatus according to an embodiment.

FIG. 3 is a flowchart illustrating an outline of a plasma processing method according to an embodiment.

FIG. 4 is a cross-sectional view schematically illustrating an outline of a configuration of a main body formed with a precoat according to an embodiment.

FIG. 5 is a cross-sectional view schematically illustrating an outline of a configuration of a main body formed with a precoat according to an embodiment.

FIG. 6 is a ternary diagram illustrating the ratio of a crystal structure of a precoat.

FIGS. 7A to 7D are cross-sectional views illustrating the effect of a precoat on an attraction force between a substrate and an electrostatic chuck in chronological order.

FIG. 8 is a cross-sectional view schematically illustrating an outline of a substrate support forming a precoat and another coat layer according to an embodiment.

FIG. 9 is a flowchart illustrating an outline of a plasma processing method according to an embodiment.

FIG. 10 is a flowchart illustrating an outline of a plasma processing method according to an embodiment.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

In the manufacturing process of semiconductor devices, a semiconductor wafer (hereinafter referred to as a “substrate”) is disposed on a substrate support in a processing chamber, and various processing steps are performed using a process gas to perform a predetermined processing on the substrate. Further, dry cleaning in the processing chamber may be performed to remove residues remaining from the processing steps.

An electrostatic chuck (ESC) that electrically attracts and supports the substrate is used as the substrate support. A surface of the electrostatic chuck may be fluorinated due to deposits such as fluorine remaining from the processing steps. Fluorination of the electrostatic chuck surface may lead to adverse effects on the manufacturing process. For example, friction between the fluorinated electrostatic chuck surface and the substrate may cause surface damage, or there may be changes in electrical properties. In this case, various effects may occur such as abnormal heat transfer due to changes in the surface area of the electrostatic chuck, generation of particles in a substrate processing space, and improper electrostatic attraction. These effects have become increasingly significant in recent years due to a demand for performing the above-mentioned manufacturing process at high power and for a long time. From the viewpoint of mitigating these effects, it has been proposed to form a precoat on the electrostatic chuck surface.

U.S. Pat. No. 5,952,060 discloses a method of forming a carbon-based coating on a member in a processing chamber by an in-situ process. For example, as described therein, the carbon-based coating is a diamond coating or a diamond-like carbon (DLC) coating, and the method includes supplying a hydrocarbon gas into the chamber, generating plasma from the hydrocarbon gas to form the carbon-based coating, degassing the hydrocarbon gas, and then performing a conventional process including etching the substrate. Thus, it is described that the members in the processing chamber are protected from damage caused by ionized gas species.

Upon a thorough investigation of such a precoat by the present inventors, it has been recognized that when forming a precoat on the electrostatic chuck surface, it is necessary to consider an electrical attraction force between the electrostatic chuck and the substrate with the precoat interposed therebetween. For example, the electrostatic chuck comes into contact, at a substrate support surface thereof, with a substrate lower surface WB to electrically attract the substrate, but the precoat interposed between the substrate support surface and the substrate lower surface WB may have effects on the attraction force.

Regarding the effects on the attraction force mentioned above, for example, when the conductivity of the precoat is too high, charges may easily move between the precoat and the substrate, which leads to the inability to maintain a potential difference between the electrostatic chuck and the substrate, thereby reducing the attraction force. A reduction in attraction force may cause concerns such as substrate misalignment or leakage of a heat transfer gas supplied to the substrate lower surface. Meanwhile, when the conductivity of the precoat is too low, there may be concerns about a lot of residual charges remaining on the substrate and the electrostatic chuck during dechucking (terminating the attraction of the substrate by the electrostatic chuck and separating the substrate from the electrostatic chuck), resulting in abnormal dechucking due to residual attraction. Residual attraction is an example of inadequate attraction force, and details will be described later. Accordingly, it is necessary to ensure an appropriate attraction force between the electrostatic chuck and the substrate when forming the precoat.

U.S. Pat. No. 5,952,060 describes the property of the carbon-based coating to prevent chemical damage caused by ionized gas species, but does not describe, for example, the effect thereof on an attraction force between the electrostatic chuck and the substrate. The carbon-based coating described in U.S. Pat. No. 5,952,060 is a diamond coating having a thickness of 1 μm to 50 μm, or a DLC coating of 0.5 μm to 50 μm. DLC in the DLC coating is described as amorphous carbon (hard carbon or α-carbon). Upon a thorough investigation by the present inventors, it has been recognized that the above-mentioned carbon-based coating cannot ensure an appropriate attraction force between at least the electrostatic chuck and the substrate.

Therefore, the technology according to the present disclosure forms a precoat capable of ensuring an appropriate attraction force between the electrostatic chuck and the substrate. For example, the ratio of a crystal structure of hydrocarbon contained in the precoat is adjusted to an appropriate level to adjust the conductivity of the precoat to an appropriate level, thereby ensuring an appropriate attraction force.

Hereinafter, a configuration of a substrate processing apparatus according to the present embodiment will be described with reference to the drawings. In this specification, the same reference numerals will be given to elements having substantially the same functional configuration, and redundant descriptions thereof will be omitted.

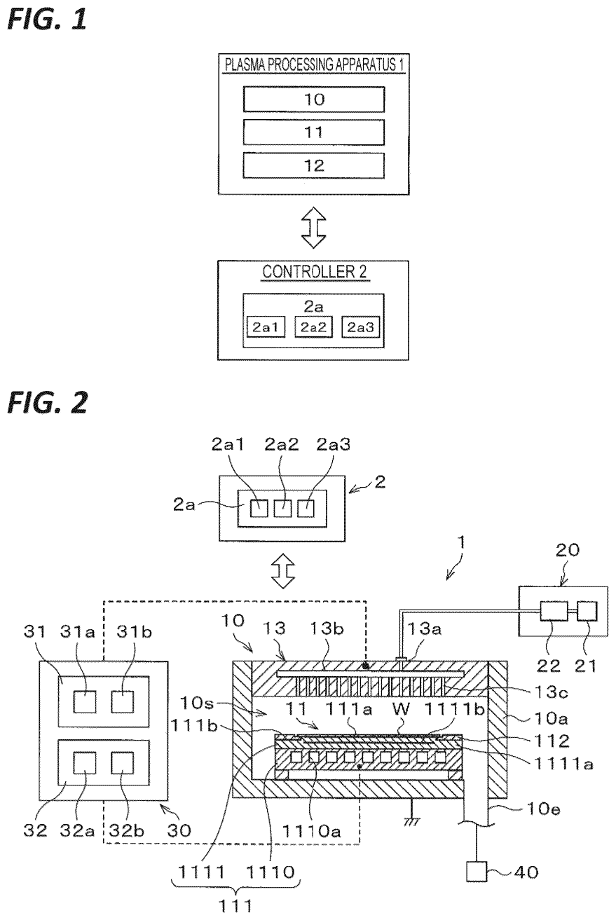

FIG. 1 is a diagram illustrating a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support unit 11, and a plasma generation unit 12. The plasma processing chamber 10 has a plasma processing space. Further, the plasma processing chamber 10 has at least one gas supply port for supplying at least one process gas into the plasma processing space, and at least one gas discharge port for discharging the gas from the plasma processing space. The gas supply port is connected to a gas supply unit 20 as described below, and the gas discharge port is connected to an exhaust system 40 as described below. The substrate support unit 11 is arranged in the plasma processing space and has a substrate support surface for supporting a substrate.

The plasma generation unit 12 is configured to generate a plasma from at least one process gas supplied into the plasma processing space. The plasma generated in the plasma processing space may be a capacitively-coupled plasma (CCP), inductively-coupled plasma (ICP), electron-cyclotron-resonance (ECR) plasma, helicon wave excitation plasma (HWP), or surface wave plasma (SWP), among others. Further, various types of plasma generation units, including an alternating current (AC) plasma generation unit and a direct current (DC) plasma generation unit, may be used. In an embodiment, an AC signal (AC power) used in the AC plasma generation unit has a frequency within the range of 100 kHz to 10 GHz. Thus, the AC signal includes a radio frequency (RF) signal and a microwave signal. In an embodiment, the RF signal has a frequency within the range of 100 kHz to 150 MHz.

The controller 2 processes computer-executable instructions that cause the plasma processing apparatus 1 to execute various steps described in the present disclosure. The controller 2 may be configured to control each element of the plasma processing apparatus 1 so as to execute various steps described herein. In an embodiment, a part or the entirety of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may be configured to perform various control operations by reading a program from the storage 2a2 and executing the read program. This program may be stored in advance in the storage 2a2, or may be acquired via a medium when necessary. The acquired program is stored in the storage 2a2 and is executed by the processor 2a1 when the processor 2a1 reads the program from the storage 2a2. The medium may be any of various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

Next, a configuration example of a capacitively-coupled plasma processing apparatus 1 will be described as an example of the plasma processing apparatus 1. FIG. 2 is a diagram illustrating a configuration example of the capacitively-coupled plasma processing apparatus 1.

The capacitively-coupled plasma processing apparatus 1 includes the plasma processing chamber 10, the gas supply unit 20, a power supply 30, and the exhaust system 40. Further, the plasma processing apparatus 1 includes the substrate support unit 11 and a gas introduction unit. The gas introduction unit is configured to introduce at least one process gas into the plasma processing chamber 10. The gas introduction unit includes a shower head 13. The substrate support unit 11 is arranged in the plasma processing chamber 10. The shower head 13 is located above the substrate support unit 11. In an embodiment, the shower head 13 constitutes at least a part of the ceiling of the plasma processing chamber 10. The plasma processing chamber 10 has a plasma processing space 10s defined by the shower head 13, a sidewall 10a of the plasma processing chamber 10, and the substrate support unit 11. The plasma processing chamber 10 is grounded. The shower head 13 and the substrate support unit 11 are electrically insulated from a case of the plasma processing chamber 10.

The substrate support unit 11 includes a main body 111 and a ring assembly 112. The main body 111 includes a central region and an annular region. The central region constitutes a substrate support surface 111a for supporting a substrate W, and the annular region constitutes a ring support surface 111b for supporting the ring assembly 112. A wafer is an example of the substrate W. The ring support surface 111b of the main body 111 surrounds the substrate support surface 111a of the main body 111 in plan view. The substrate W is disposed on the substrate support surface 111a of the main body 111, and the ring assembly 112 is disposed on the ring support surface 111b of the main body 111 to surround the substrate W on the substrate support surface 111a of the main body 111.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b arranged in the ceramic member 1111a. The ceramic member 1111a has the substrate support surface 111a. In an embodiment, the ceramic member 1111a also has the ring support surface 111b. Another member surrounding the electrostatic chuck 1111, such as an annular electrostatic chuck or an annular insulating member, may have the ring support surface 111b. In this case, the ring assembly 112 may be disposed on the annular electrostatic chuck or the annular insulating member, or may be disposed on both the electrostatic chuck 1111 and the annular insulating member. Further, at least one RF/DC electrode, which is coupled to a RF power supply 31 and/or DC power supply 32 as described below, may be arranged in the ceramic member 1111a. In this case, the at least one RF/DC electrode functions as a lower electrode. When a bias RF signal and/or DC signal as described below is supplied to the at least one RF/DC electrode, the RF/DC electrode is also referred to as a bias electrode. The conductive member of the base 1110 and the at least one RF/DC electrode may function as a plurality of lower electrodes. Further, the electrostatic electrode 1111b may function as a lower electrode. Accordingly, the substrate support unit 11 includes at least one lower electrode.

The ring assembly 112 includes one or a plurality of annular members. In an embodiment, the one or plurality of annular members include one or a plurality of edge rings and at least one cover ring. The edge ring is made of a conductive material or insulating material, and the cover ring is made of an insulating material.

Further, the substrate support unit 11 may include a temperature regulation module configured to regulate at least one of the electrostatic chuck 111, the ring assembly 112, and the substrate W to a target temperature. The temperature regulation module may include a heater, a heat transfer medium, a flow path 1110a, or a combination thereof. A heat transfer fluid such as brine or gas flows through the flow path 1110a. In an embodiment, the flow path 1110a is formed in the base 1110, and one or a plurality of heaters are arranged in the ceramic member 1111a of the electrostatic chuck 1111. Further, the substrate support unit 11 may include a heat transfer gas supply configured to supply a heat transfer gas to a gap between the backside of the substrate W and the substrate support surface 111a.

The shower head 13 is configured to introduce at least one process gas or a precoat gas as described below from the gas supply unit 20 into the plasma processing space 10s. The shower head 13 has at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include one or a plurality of side gas injectors (SGI) attached to one or a plurality of openings formed in the sidewall 10a, in addition to the shower head 13.

The gas supply unit 20 may include at least one gas source 21 and at least one flow controller 22. In an embodiment, the gas supply unit 20 is configured to supply at least one process gas from each corresponding gas source 21 to the shower head 13 via each corresponding flow controller 22. Each flow controller 22 may include, for example, a mass flow controller or a pressure-controlled flow controller. Furthermore, the gas supply unit 20 may include at least one flow-rate modulation device that modulates or pulses the flow rate of at least one process gas.

The gas supply unit 20 may include at least one gas source 21, which supplies a precoat gas as described below, and at least one corresponding flow controller 22.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. This allows for the generation of a plasma from at least one process gas supplied to the plasma processing space 10s. Accordingly, the RF power supply 31 may function as at least a part of the plasma generation unit 12. Further, when a bias RF signal is supplied to at least one lower electrode, a bias potential occurs on the substrate W, enabling ion components of the generated plasma to be drawn into the substrate W.

In an embodiment, the RF power supply 31 includes a first RF generation unit 31a and a second RF generation unit 31b. The first RF generation unit 31a is coupled to at least one lower electrode and/or at least one upper electrode via at least one impedance matching circuit and is configured to generate a source RF signal (source RF power) for plasma generation. In an embodiment, the source RF signal has a frequency within the range of 100 MHz to 150 MHz. In an embodiment, the first RF generation unit 31a may be configured to generate a plurality of source RF signals having different frequencies. The generated one or plurality of source RF signals are supplied to at least one lower electrode and/or at least one upper electrode.

The second RF generation unit 31b is coupled to at least one lower electrode via at least one impedance matching circuit, and is configured to generate a bias RF signal (bias RF power). The frequency of the bias RF signal may be the same as or different from that of the source RF signal. In an embodiment, the bias RF signal has a lower frequency than that of the source RF signal. In an embodiment, the bias RF signal has a frequency within the range of 100 kHz to 60 MHZ. In an embodiment, the second RF generation unit 31b may be configured to generate a plurality of bias RF signals having different frequencies. The generated one or plurality of bias RF signals are supplied to at least one lower electrode. Further, in various embodiments, at least one of the source RF signal and the bias RF signal may be pulsed.

Further, the power supply 30 may include the DC power supply 32 coupled to the plasma processing chamber 10. The DC power supply 32 includes a first DC generation unit 32a and a second DC generation unit 32b. In an embodiment, the first DC generation unit 32a is connected to at least one lower electrode and is configured to generate a first DC signal. The generated first DC signal is applied to at least one lower electrode. In an embodiment, the second DC generation unit 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulses may have a rectangular, trapezoidal, triangular pulse waveform or a combination thereof. In an embodiment, a waveform generation unit for generating the sequence of voltage pulses from DC signals is connected between the first DC generation unit 32a and at least one lower electrode. Accordingly, the first DC generation unit 32a and the waveform generation unit constitute a voltage pulse generation unit. When the second DC generation unit 32b and the waveform generation unit constitute the voltage pulse generation unit, the voltage pulse generation unit is connected to at least one upper electrode. The voltage pulses may have positive polarity or negative polarity. Further, the sequence of voltage pulses may include one or a plurality of positive-polarity voltage pulses, or one or a plurality of negative-polarity voltage pulses within one cycle. The first and second DC generation units 32a and 32b may be provided in addition to the RF power supply 31, and the first DC generation unit 32a may be provided in place of the second RF generation unit 31b.

The exhaust system 40 may be connected to, for example, a gas discharge port 10e formed at the bottom of the plasma processing chamber 10. The exhaust system 40 may include a pressure adjustment valve and a vacuum pump. The pressure in the plasma processing space 10s is adjusted by the pressure adjustment valve. The vacuum pump may include a turbomolecular pump, a dry pump, or a combination thereof.

### First Embodiment

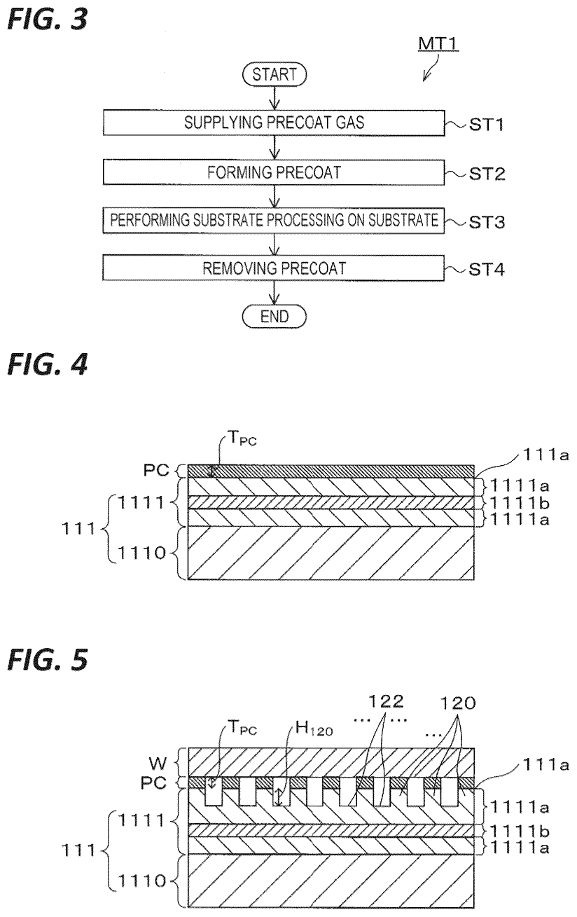

Next, an etching method MT1 according to a first embodiment will be described with reference to FIGS. 3 and 4. FIG. 3 is a flowchart illustrating an outline of the etching method MT1 according to the first embodiment. In the etching method MT1, it is possible to form a precoat PC in the plasma processing chamber 10 using the above-mentioned plasma processing system. In the present disclosure, plasma processing includes not only forming the precoat PC before the processing of the substrate W such as etching or film formation, but also forming the precoat PC before dry cleaning of the inside of the plasma processing chamber 10. Further, it includes removing the formed precoat PC. The precoat PC is an example of a carbon-containing film according to the present disclosure.

First, a precoat gas is supplied into the evacuated plasma processing chamber 10 (step ST1). Hereinafter, descriptions will be made on a case where a single component gas such as hydrocarbon gas (CH gas) is used as the precoat gas. However, the precoat gas is not limited to this, and a desired gas containing carbon and hydrogen may be used. For example, the gas containing carbon and hydrogen may be a single component gas such as CH gas or hydrofluorocarbon gas (CHF gas), or may be a mixed gas of one selected from the group consisting of a CH gas, CHF gas, and fluorocarbon gas (CF gas) and a hydrogen-containing gas such as hydrogen gas (H₂ gas). Among these, a single component gas such as CH gas or a mixed gas containing a CH gas, which does not contain fluorine (F), may be used as the precoat gas. Any of saturated hydrocarbon (alkane) represented by CₙH₂ₙ₊₂ such as CH₄ and unsaturated hydrocarbon (alkene, alkyne) containing double bonds or triple bonds such as C₂H₄ or C₂H₂ are applicable as for the CH gas, and the CH gas is not particularly limited.

Further, the precoat gas may be a mixed gas containing the above-mentioned single component gas or mixed gas and an inert gas in a desired ratio. The inert gas may be a noble gas such as argon (Ar), or a nitrogen (N₂) gas.

In step ST1, the pressure in the chamber is controlled to 100 mTorr or more by supplying the precoat gas into the chamber. When the pressure in the chamber is lower than 100 mTorr, the precoat PC is mainly composed of graphite, which may result in a reduction in attraction force due to reasons as described below. The upper limit of the pressure in the chamber is not particularly limited, but may be 1,000 mTorr or less when using a general etching device.

Next, a plasma is generated from the precoat gas to form the precoat PC in the plasma processing chamber 10 (step ST2). FIG. 4 is a cross-sectional view schematically illustrating an outline of a configuration of the main body 111 formed with the precoat PC by the etching method MT1 according to the present embodiment. In the present embodiment, a plasma is generated from a CH gas since the precoat gas is the CH gas. The inside of the plasma processing chamber 10 includes at least the substrate support surface 111a of the substrate support unit 11 (surface of the electrostatic chuck 1111). In an embodiment, the substrate support surface 111a has a plurality of recesses to which a heat transfer gas is supplied. In an embodiment, the substrate support surface 111a may have a plurality of protrusions 120 (dots) for supporting the substrate W, or may not have the protrusions 120.

FIG. 5 is a cross-sectional view schematically illustrating an outline of a configuration of the main body 111 formed with the precoat PC by the etching method MT1 according to the present embodiment, in a case where the substrate support surface 111a has the protrusions 120. In FIG. 5, the precoat PC is formed at least on the upper surface of the plurality of protrusions 120. In other words, as illustrated, in a state where the substrate W is supported by the substrate support unit 11 (electrostatic chuck 1111), the precoat PC may be formed only on a portion of the substrate support unit 11 in contact with the substrate W, and may not be formed on the other portion of the protrusions 120 (side surface of the protrusions 120), recesses 122, and the like. Further, in this case, the thickness T_{PC} of the precoat PC may be formed to be thinner than the height H₁₂₀ of the protrusions 120 (distance between the upper surface of the protrusions 120 and the lower surface of the recesses 122).

Referring back to FIGS. 3 and 4, when the substrate support surface 111a does not have the protrusions 120, the precoat PC may be formed on the entire substrate support surface 111a. In addition, the precoat PC may be formed on a surface of a desired component in the plasma processing chamber 10 exposed to the plasma processing space 10s, such as the ceiling or sidewall 10a of the plasma processing chamber 10.

The thickness T_{PC} of the precoat PC may be 5 nm or more. When the thickness is thinner than 5 nm, it may not be possible to form a stable film, leading to noticeable surface irregularities, and the precoat PC may not be formed on a part of the substrate support surface 111a. The thickness T_{PC} of the precoat PC may particularly be 10 nm or more. However, there is no particular upper limit of the thickness T_{PC} of the precoat PC. Considering the time and cost required to form the precoat PC, the thickness T_{PC} of the precoat PC may be 100 nm or less.

After forming the precoat PC, the etching of the substrate W is executed (step ST3). In step ST3, the substrate W is loaded into the plasma processing chamber 10, is disposed on the substrate support surface 111a where the precoat PC is formed, and is supplied with a desired process gas, so that a plasma is generated from the process gas to etch the substrate W. In an embodiment, after executing step ST3, the substrate W is unloaded from the plasma processing chamber 10, and the precoat PC is removed (step ST4). There is not particular limitation on the method of removing the precoat PC, and it may be accomplished by dry cleaning under desired conditions. In an embodiment, dry cleaning may be performed by generating a plasma from an oxygen-containing gas such as O₂ gas other than a fluorine-containing gas. Further, step ST4 may be performed after executing step ST3 once, or may be performed after executing step ST3 a predetermined number of times. In other words, dry cleaning may be performed after performing a cycle, including disposing the substrate W on the substrate support surface 111a and etching the substrate W, one or more times. Step ST4 is optional and is not essential.

In the etching method MT1, plasma generation conditions, such as the flow rate of the precoat gas, temperature in the chamber, and RF frequency and power, may be determined in advance for each apparatus configuration. The plasma generation conditions may be determined by experiments or simulations. When the plasma generation conditions are determined by experiments, the experiments may be performed prior to the etching method MT1, and the determined conditions may be stored in the controller 2. Further, when executing the etching method MT1, the stored conditions may be read before step ST1. In addition, examples of the apparatus configuration include differences depending on whether the RF electrode is of an upper incut type or lower incut type as well as the distance between upper and lower electrodes. Further, the plasma generation conditions refer to conditions under which the precoat PC having properties as described below may be formed by executing step ST2 and where the plasma from the precoat gas does not damage the electrostatic chuck 1111.

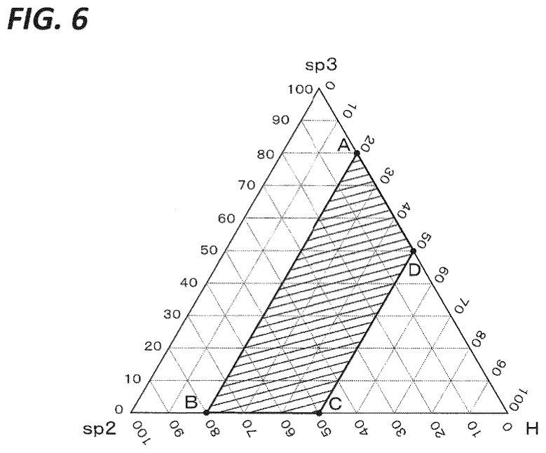

Next, an example of the properties of the precoat PC formed by the etching method MT1 according to the present embodiment will be described with reference to FIG. 6. FIG. 6 is a ternary diagram of (sp3:sp2:H) illustrating the ratio [%] of a crystal structure of hydrocarbon.

The precoat PC according to the present embodiment contains H atoms in the amount of 20 atomic % or more and 50 atomic % or less. Further, in an embodiment, a desirable property of the precoat PC is defined as the ratio [%] of the crystal structure in the ternary diagram.

In FIG. 6 illustrating the ternary diagram of (sp3:sp2:H), the ratio [%] of the precoat PC is enclosed within a quadrangle ABCD formed by four points: point A (sp3:sp2:H)=(80:0:20), point B (sp3:sp2:H)=(0:80:20), point C (sp3:sp2:H)=(0:50:50), and point D (sp3:sp2:H)=(50:0:50).

Here, the ternary diagram of (sp3:sp2:H) will be described. In DLC, carbon atoms mainly form crystals with three types of bonding forms:sp3 bonds representing a diamond structure, sp2 bonds representing a graphite structure, and bonds with hydrogen atoms. For example, if the precoat PC has a ratio [%] represented by point A (sp3:sp2:H)=(80:0:20), it indicates that a crystal structure of the precoat PC contains 80% sp3 bonds, 0% sp2 bonds (i.e., none), and 20% bonds with hydrogen atoms.

The ratio [%] of (sp3:sp2:H) may be acquired by, for example, Raman spectroscopic analysis. In Raman spectroscopic analysis, the precoat PC is irradiated with visible laser light as excitation light to acquire the Raman spectrum of scattered light. The peak intensity ratio ID/IG may be acquired from the D-band peak and G-band peak in the Raman spectrum, and the ratio [%] of (sp3:sp2:H) may be calculated based on the peak intensity ratio. The ratio [%] of (sp3:sp2:H) calculated in this way is plotted on the ternary diagram illustrated in FIG. 6, and it may be determined whether the plot is enclosed within the quadrangle ABCD. When “sp3, sp2, or H is 0%” in the above calculated ratio [%], it is not limited to a case where they are not actually included at all, but may refer to a case where they are included to an extent undetectable by Raman spectroscopy analysis.

The diamond coating described in U.S. Pat. No. 5,952,060 is considered to contain little hydrogen, with most carbon atoms exhibiting sp3 bonds representing a diamond structure. The ratio [%] in this case is typically (sp3:sp2:H)≈(100:0:0). Further, the DLC described in U.S. Pat. No. 5,952,060 is amorphous carbon (hard carbon or α-carbon). Amorphous carbon is known to contain little hydrogen and have a high proportion of sp2 in a crystal structure thereof. The ratio [%] in this case is typically (sp3:sp2:H)≈(0:100:0). Accordingly, the diamond coating and DLC coating described in U.S. Pat. No. 5,952,060 are not included in the precoat PC according to the present embodiment.

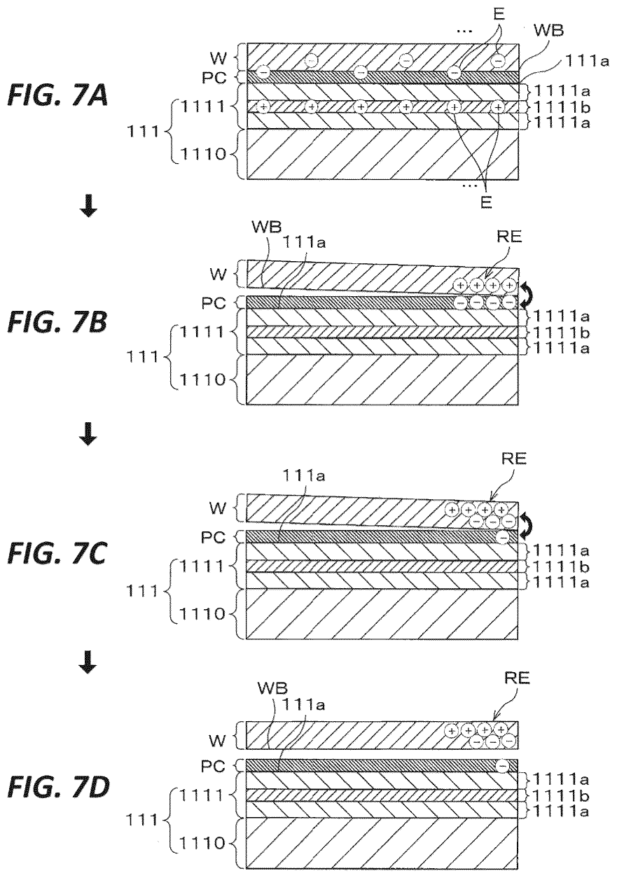

Next, the significance of configuring the precoat PC according to the present embodiment as described above will be described with reference to FIGS. 7A to 7D. FIGS. 7A to 7D are cross-sectional views illustrating the effect of the precoat PC on the above-mentioned attraction force in chronological order. The precoat PC illustrated in FIGS. 7A to 7D is the precoat PC according to the present embodiment, and contains the ratio [%] of a crystal structure included in the above-mentioned quadrangle ABCD.

FIG. 7A illustrates a state where the substrate W is disposed on the surface of the electrostatic chuck 1111 where the precoat PC according to the present embodiment is formed at the substrate support surface 111a, and the substrate lower surface WB is in contact with the precoat PC. In this state, positive charges E are supplied to the electrostatic electrode 1111b, causing relatively negative charges E to occur in the substrate W. They attract each other electrically by these charges E. Some of the negative charges E are moving from the substrate W to the precoat PC. However, since the precoat PC has sufficiently low conductivity (high insulation), it maintains a potential difference due to the charges E between the electrostatic electrode 1111b and the substrate W, thereby not weakening electrostatic attraction. Accordingly, the substrate may be attracted and supported with a sufficient attraction force.

In FIG. 7B, during dechucking, the supply of positive charges E to the electrostatic chuck 1111 is stopped. At this time, negative residual charges RE remain in the precoat PC, and relatively positive residual charges RE occur in the substrate W. In this state, the substrate W is pushed upward with a pin (not illustrated) provided at the main body 111. At this time, the contact between the substrate lower surface WB and the precoat PC gradually moves away from a portion pushed by the pin, eventually reaching a state where they are in contact at a single point with a tiny area. The residual charges RE move to this single point as the substrate lower surface WB and the precoat PC move apart. Therefore, opposite residual charges RE are concentrated on the substrate lower surface WB and the precoat PC at this single point, creating a relatively large potential difference. The attraction at this single point with the occurrence of residual charges RE is referred to as residual attraction. After stopping the supply of charges E, if necessary, neutralization to reduce the residual charges RE in the electrostatic chuck 1111 may be performed by applying a reverse potential to the electrostatic chuck 1111 or by a plasma field. However, it may be difficult to completely prevent the residual charges even with neutralization depending on the surface condition of the electrostatic chuck 1111.

In FIG. 7C, the precoat PC according to the present embodiment has a degree of conductivity sufficient for the residual charges RE to move between the substrate and the precoat PC in the presence of a relatively large potential difference as described above. The double-ended arrow in the drawing indicates movement of the residual charges RE. The movement of the residual charges RE between the substrate lower surface WB and the precoat PC as illustrated in FIG. 7C from the state illustrated in FIG. 7B alleviates the potential difference.

In FIG. 7D, residual attraction is weakened as the potential difference is alleviated due to the movement of the residual charges RE, allowing for smooth dechucking by the pushing force of the pin. The strength of residual attraction may be evaluated based on the output of the pin pushing the substrate, i.e., torque (pin torque). For example, a high pin torque during dechucking may be evaluated as strong residual attraction, while a low pin torque may be evaluated as weak residual attraction.

The movement of the residual charges RE between the substrate W and the precoat PC according to the present embodiment is permissible when the substrate lower surface WB and the precoat PC are in contact at the above-mentioned single point within a narrow range, creating a relatively large potential difference. Accordingly, the electrical properties of the precoat PC according to the present embodiment do not impair the attraction force during normal electrostatic attraction by the electrostatic chuck 1111. In other words, the precoat PC according to the present embodiment has a sufficiently low conductivity to maintain a potential difference between the substrate W and the electrostatic electrode 1111b during normal electrostatic attraction as illustrated in FIG. 7A, but has electrical properties that allow for the movement of the residual charges RE under a relatively large potential difference when the residual charges RE are concentrated at the single point as illustrated in FIGS. 7B and 7C.

Here, in contrast to the precoat PC according to the present embodiment, a case where a precoat PC with a low conductivity is formed as a comparative example will be described. For example, the precoat PC of the comparative example has properties that fall within a region at the left of the line segment AB in FIG. 6. In FIG. 7B, the residual charges RE may not move between the substrate W and the precoat PC due to the low conductivity of the precoat PC as the comparative example. In other words, there would be no movement of the residual charges RE as indicated by the double-ended arrow in the drawing, and the alleviation of the potential difference as illustrated in FIG. 7C may not be realized. It is considered that when the pin further pushes the substrate in this state, sudden attraction release may occur, thereby causing the substrate W to bounce up or leading to scratches on the substrate W. The attraction force in this state would not be appropriate.

According to the precoat PC of the present embodiment, it is possible to prevent residual attraction by facilitating the movement of the residual charges RE during dechucking without weakening the attraction force of the substrate W by the electrostatic chuck 1111. Further, the precoat PC according to the present embodiment may be formed to have surface properties and hardness that prevent physical damage to the substrate lower surface WB due to friction between the precoat and the substrate W and that render it resistant to damage. In this way, the replacement lifespan of the electrostatic chuck 1111 may be extended. Further, the precoat PC according to the present embodiment may be formed to have a film density that prevents particles generated from the surface of the electrostatic chuck 1111 from passing through the precoat PC and being released into the plasma processing space 10s. This formation helps in preventing contamination.

### Second Embodiment

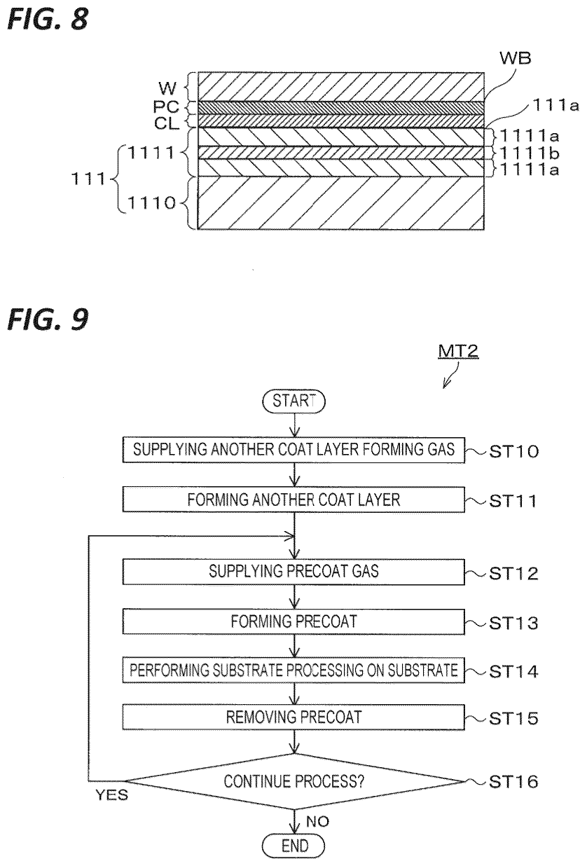

Next, an etching method MT2 according to a second embodiment will be described with reference to FIGS. 8 and 9. FIG. 8 is a cross-sectional view schematically illustrating an outline of the electrostatic chuck 1111 formed with the precoat PC and another coat layer CL by the etching method MT2 according to the second embodiment. FIG. 9 is a flowchart illustrating an outline of the etching method MT2 according to the second embodiment.

In FIG. 8, in the etching method MT2, another coat layer CL is formed on the upper surface of the electrostatic chuck 1111 and the precoat PC, which satisfies the properties of the present disclosure, is formed at the outermost side in contact with the substrate lower surface WB, through the use of the above-mentioned plasma processing system. The precoat PC that satisfies the properties of the present disclosure refers to the precoat PC that satisfies the properties described in the first embodiment. When the properties described above are satisfied in the present embodiment as well, the present embodiment exhibits the same actions and effects as those described in the first embodiment.

The other coat layer CL is an insulating film. The other coat layer CL may not satisfy the properties of the precoat PC according to the present disclosure. The other coat layer CL may be a Si-containing film made of, for example, SiO₂, or a C-containing film made of, for example, a diamond coat. Further, the thickness of the other coat layer CL may be on the order of microns.

In FIG. 9, in the etching method MT2, the other coat layer CL is formed prior to forming the precoat PC. For example, first, a gas for forming the other coat layer such as a Si-containing gas or C-containing gas is supplied into the plasma processing chamber 10 (step ST10). Then, a plasma is generated from that gas to form the other coat layer CL (step ST11). Subsequently, a precoat gas is supplied to form the precoat PC on the other coat layer CL (steps ST12 and ST13). Thereafter, the substrate W is loaded into the plasma processing chamber 10, is disposed on the substrate support surface 111a where the precoat PC is formed, and is subjected to substrate processing including etching (step ST14). Finally, the substrate W may be unloaded from the plasma processing chamber 10, and the precoat PC may be removed (step ST15). Details of steps ST12 to ST15 are the same as steps ST1 to ST4 in the etching method MT1 according to the first embodiment.

In an embodiment, after removing the precoat PC, it may be determined whether to continue the manufacturing process (step ST16). When the manufacturing process is continued in step ST16, a sequence of steps ST12 to ST16 is executed again, and the sequence is repeated in the same manner until the manufacturing process is completed. In other words, in the present embodiment, the precoat PC is formed and removed each time substrate processing, including etching, is performed on the substrate W. When the manufacturing process is not continued in step ST16, the process is terminated.

In the etching method MT2, plasma generation conditions such as the pressure and flow rate of the other coat layer forming gas, temperature in the chamber, and RF frequency and power in steps ST10 and ST11 may be applied based on the type of other coat layer forming gas and the characteristics of the other coat layer CL to be formed such as film thickness and insulating properties. Further, plasma generation conditions in steps ST12 and ST13 may be applied as described in the etching method MT1 of the first embodiment.

In the etching method MT2, the other coat layer CL is formed through steps ST10 and ST11, but is not limited thereto. In other words, the other coat layer CL may be formed by a conventional method as desired as long as it is formed to have the above-mentioned characteristics as well as sufficient attraction as described below.

Next, the significance of configuring the precoat PC and the other coat layer CL as described above according to the second embodiment will be described. The electrostatic chuck 1111 is composed of the ceramic member 1111a, and continuing substrate processing may result in the generation of particles such as ceramic fragments from a weakened surface of the ceramic member 1111a. Since these ceramic fragments have excellent corrosion resistance, they may not be completely removed by dry cleaning and may remain in the plasma processing chamber 10. These ceramic fragments may compromise the adhesion of the precoat PC to a component within the plasma processing chamber 10 where the above-described precoat PC needs to be formed.

In view of the above, in the etching method MT2 according to the second embodiment, the other coat layer CL is formed, and the precoat PC is formed on the other coat layer CL. By using the other coat layer CL that has sufficient adhesion to the above-mentioned component, the precoat PC formed on the other coat layer CL may be maintained in close contact with that component. Examples of the other coat layer CL exhibiting sufficient adhesion to the component include a Si-containing film made of, e.g., SiO₂, and a C-containing film made of a diamond coat as described above. The other coat layer CL described above may maintain the adhesion of the precoat PC even when the ceramic fragments remain.

From another viewpoint, when using the other coat layer CL alone, there are issues with residual attraction as described above because the other coat layer CL is insulating. Further, when using the other coat layer CL alone, it may wear out due to friction with the substrate W, requiring periodic reattachment (removal and re-formation). However, when reattaching the other coat layer CL, strong cleaning using a halogen gas is required due to high mechanical stability of the other coat layer CL, which may potentially damage the electrostatic chuck 1111. In contrast, by forming the precoat PC, which is relatively easy to reattach, on the other coat layer CL, the precoat PC has the effect of protecting the other coat layer CL. This allows for the relatively easy attachment of the precoat PC alone at regular intervals, reducing the frequency of reattachment of the other coat layer CL. In other words, in the second embodiment, the precoat PC complements the issues of residual attraction and difficulty in reattachment in the other coat layer CL, while the other coat layer CL complements the adhesion issues in the precoat PC. Thus, the precoat may serves as a suitable protective layer that resolves the problem of residual attraction and provide excellent adhesion and high maintenance efficiency for reattachment.

### Third Embodiment

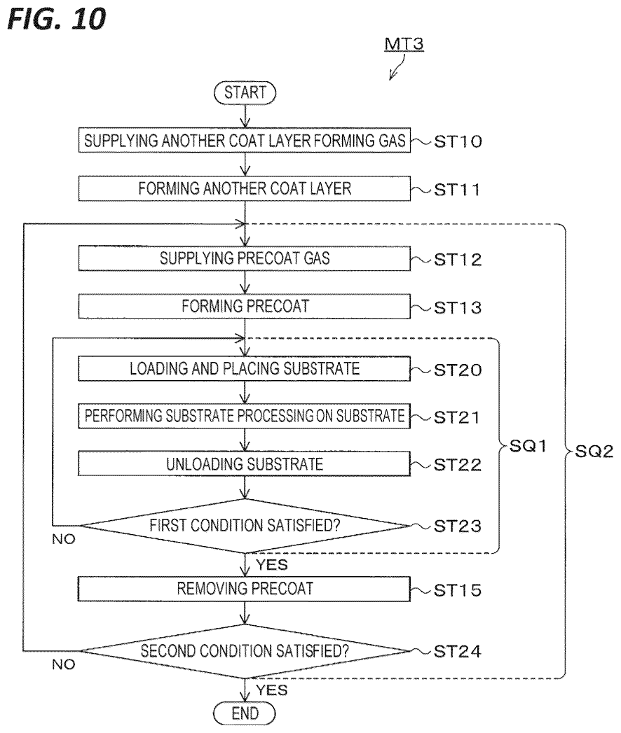

Next, an etching method MT3 according to a third embodiment will be described with reference to FIG. 10. FIG. 10 is a flowchart illustrating an outline of the etching method MT3 according to the third embodiment. Outline of a configuration of the precoat PC and the other coat layer CL formed on the electrostatic chuck 1111 by the etching method MT3 is the same as in FIG. 8 illustrating the etching method MT2 according to the second embodiment. Further, steps ST10 to ST13 and ST15 in FIG. 10 are the same as in the etching method MT2 according to the second embodiment.

In FIG. 10, when forming the other coat layer CL, the etching method MT3 repeatedly executes a first sequence SQ1, including loading of the substrate W (step ST20), substrate processing (step ST21), and unloading of the substrate W (step ST22), until a first condition is satisfied. Further, the precoat PC is removed when the first condition is satisfied, and thereafter, the etching method MT3 repeatedly executes a second sequence SQ2, including formation of the precoat PC (steps ST12 and ST13), the first sequence SQ1 (steps ST20 to ST23), and removal of the precoat PC (step ST15), until a second condition is satisfied.

Here, the first condition may be, for example, the number of repetitions of the first sequence SQ1 (number of processed substrates W), the number of processing lots of the substrate W, or the plasma processing time.

The second condition may be, for example, the number of repetitions of the second sequence SQ2 (number of processed substrates W), the number of processing lots of the substrate W, or the plasma processing time.

According to the etching method MT3 of the third embodiment, the following actions and effects are obtained in addition to achieving the actions and effects of the etching methods MT1 and MT2 according to the first and second embodiments. In other words, the use of the formed precoat PC continues until the first condition is satisfied, and once the first condition is satisfied, the precoat PC may be reattached. This allows maintaining the precoat PC with suitable properties. Further, according to the etching method MT3, the use of the formed other coat layer CL continues until the second condition is satisfied, and once the second condition is satisfied, the manufacturing process is terminated and maintenance such as reattachment of the other coat layer CL may be performed. This enables maintaining the other coat layer CL with suitable properties and ensures the proper adhesion of the precoat PC.

The embodiments disclosed herein should be considered to be exemplary and not limitative in all respects. The above embodiments may be omitted, replaced, or modified in various forms without departing from the scope of the appended claims, configuration examples within the technical scope of the present disclosure, and the gist thereof. For example, the constituent requirements of the above embodiments may be arbitrarily combined. From this arbitrary combination, the actions and effects of the respective constituent requirement are naturally obtained, and other actions and effects apparent to those skilled in the art from the description in this specification are also obtained.

For example, in the etching methods MT1 to MT3, the plasma generation conditions, such as the flow rate of the precoat gas when forming the precoat PC, temperature in the chamber, and RF frequency and power are not limited, but may be set as follows. In other words, the flow rate of the precoat gas may range from about 10 sccm to 1,000 sccm. Further, the chamber temperature may range from about 10° C. to 80° C. Further, as for the RF power, the source RF power may be 1,000 W or less. By setting these conditions, it is possible to increase the proportion of bonds with hydrogen atoms in the crystal structure of the formed precoat PC, and to determine the ratio [%] included within the range of the above-mentioned quadrangle ABCD. Further, it may help in reducing damage to the electrostatic chuck 1111 by a plasma.

Further, for example, the precoat PC described above is formed as a single layer, meaning it is formed only by the layer of the precoat PC generated by a plasma from the supplied precoat gas. For example, it is also permissible to form a multi-layer precoat PC by sequentially supplying multiple types of precoat gases to stack multiple types of precoat PC.

The following configurations also belong to the technical scope of the present disclosure.

### (Appendix 1)

An etching method including:
(a) forming a carbon-containing film on a surface of an electrostatic chuck disposed in a chamber;
(b) disposing a substrate on the carbon-containing film of the electrostatic chuck; and
(c) etching the substrate with plasma,
in which (a) includes:
(a1) supplying a precoat gas containing carbon and hydrogen into the chamber and controlling a pressure in the chamber to be 100 mTorr or more and 1,000 mTorr or less; and
(a2) generating the plasma from the precoat gas.

### (Appendix 2)

The etching method according to Appendix 1, in which (a) includes controlling a surface temperature of the electrostatic chuck to be 10° C. or more and 80° C. or less.

### (Appendix 3)

The etching method according to Appendix 1 or 2, in which in (a1), a flow rate of the precoat gas is controlled to be 10 sccm or more and 1,000 sccm or less.

### (Appendix 4)

The etching method according to any one of Appendices 1 to 3, in which in (a2), source RF power for generating the plasma is 1,000 W or less.

### (Appendix 5)

The etching method according to any one of Appendices 1 to 4, in which the precoat gas includes a hydrocarbon gas, a hydrofluorocarbon gas, or a mixed gas of a hydrogen-containing gas and at least one selected from the group consisting of a hydrocarbon gas, a hydrofluorocarbon gas, and a fluorocarbon gas.

### (Appendix 6)

The etching method according to any one of Appendices 1 to 5, in which the precoat gas includes a hydrocarbon gas.

### (Appendix 7)

The etching method according to any one of Appendices 1 to 6, in which the precoat gas further includes an inert gas.

### (Appendix 8)

The etching method according to any one of Appendices 1 to 7, in which the carbon-containing film contains H atoms in an amount of 20 atomic % or more and 50 atomic % or less.

### (Appendix 9)

The etching method according to Appendix 8, in which, in a ternary diagram of (sp3:sp2:H) representing a ratio [%] of a crystal structure of hydrocarbon, the ratio of the carbon-containing film is enclosed within a quadrangle ABCD formed by four points:
point A (sp3:sp2:H)=(80:0:20),
point B (sp3:sp2:H)=(0:80:20),
point C (sp3:sp2:H)=(0:50:50), and
point D (sp3:sp2:H)=(50:0:50).

### (Appendix 10)

The etching method according to any one of Appendices 1 to 9, in which the carbon-containing film has a thickness of 5 nm or more.

### (Appendix 11)

The etching method according to Appendix 10, in which the thickness of the carbon-containing film is 10 nm or more and 100 nm or less.

### (Appendix 12)

The etching method according to any one of Appendices 1 to 11, in which the electrostatic chuck has a plurality of protrusions on the surface thereof, and the carbon-containing film is formed at least on an upper surface of each of the plurality of protrusions.

### (Appendix 13)

The etching method according to Appendix 12, in which the thickness of the carbon-containing film is thinner than a height of each of the plurality of protrusions.

### (Appendix 14)

The etching method according to any one of Appendices 1 to 13, in which (a) further includes forming an insulating film on the surface of the electrostatic chuck before (a1), and the carbon-containing film is formed on the insulating film.

### (Appendix 15)

The etching method according to any one of Appendices 1 to 14, in which the electrostatic chuck includes:
a ceramic member;
at least one electrode arranged in the ceramic member; and
an insulating film on a surface of the ceramic member,
the insulating film is made of a material different from the ceramic member, and the carbon-containing film is formed on the insulating film.

### (Appendix 16)

The etching method according to Appendix 14 or 15, comprising:
(d) removing the carbon-containing film; and
(e) repeating a sequence including (a) to (d).

### (Appendix 17)

The etching method according to Appendix 16, in which the insulating film contains silicon or carbon.

### (Appendix 18)

The etching method according to any one of Appendices 1 to 13, further comprising removing the carbon-containing film after performing a cycle including (b) and (c) one or more times.

### (Appendix 19)

The etching method according to Appendix 18, in which in the removing the carbon-containing film, the carbon-containing film is removed by a plasma generated from an oxygen-containing gas.

### (Appendix 20)

An etching method including:
(a) forming an insulating film on a surface of an electrostatic chuck in a chamber;
(b) forming a carbon-containing film on the insulating film;
(c) repeating a first sequence until a first condition is satisfied, the first sequence including:
   (c1) introducing a substrate into the chamber and disposing the substrate on the carbon-containing film;
   (c2) etching the substrate with plasma; and
   (c3) separating the substrate from the carbon-containing film and unloading the substrate from the chamber;
(d) removing the carbon-containing film after (c); and
(e) repeating a second sequence including (b) to (d) until a second condition is satisfied.

### (Appendix 21)

A pre-coat method of forming a pre-coat film on a surface of an electrostatic chuck arranged in a chamber, the method including:
supplying a precoat gas containing carbon and hydrogen into the chamber and controlling a pressure in the chamber to be 100 mTorr or more and 1,000 mTorr or less; and
generating plasma from the precoat gas.

### (Appendix 22)

An etching apparatus including:
a chamber including at least one gas supply port and at least one gas discharge port;
an electrostatic chuck disposed in the chamber;
a plasma generator; and
a controller,
in which the controller is configured to execute a process including:
(a) forming a carbon-containing film on the electrostatic chuck;
(b) disposing a substrate on the carbon-containing film; and
(c) etching the substrate with plasma, and
in which (a) includes:
(a1) supplying a precoat gas containing carbon and hydrogen into the chamber and controlling a pressure in the chamber to be 100 mTorr or more and 1,000 mTorr or less; and
(a2) generating the plasma from the precoat gas.

According to the present disclosure, it is possible to form a precoat that provides an appropriate attraction force between a substrate and a substrate support.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) forming a carbon-containing film on a surface of an electrostatic chuck disposed in a chamber;
(b) disposing a substrate on the carbon-containing film of the electrostatic chuck; and
(c) etching the substrate with plasma,
wherein (a) includes:
(a1) supplying a precoat gas containing carbon and hydrogen into the chamber and controlling a pressure in the chamber to be 100 mTorr or more and 1,000 mTorr or less; and
(a2) generating the plasma from the precoat gas.

2. The etching method according to claim 1, wherein (a) includes controlling a surface temperature of the electrostatic chuck to be 10° C. or more and 80° C. or less.

3. The etching method according to claim 1, wherein in (a1), a flow rate of the precoat gas is controlled to be 10 sccm or more and 1,000 sccm or less.

4. The etching method according to claim 1, wherein in (a2), source RF power for generating the plasma is 1,000 W or less.

5. The etching method according to claim 1, wherein the precoat gas includes a hydrocarbon gas, a hydrofluorocarbon gas, or a mixed gas of a hydrogen-containing gas and at least one selected from the group consisting of a hydrocarbon gas, a hydrofluorocarbon gas, and a fluorocarbon gas.

6. The etching method according to claim 1, wherein the precoat gas includes a hydrocarbon gas.

7. The etching method according to claim 1, wherein the precoat gas further includes an inert gas.

8. The etching method according to claim 1, wherein the carbon-containing film contains H atoms in an amount of 20 atomic % or more and 50 atomic % or less.

9. The etching method according to claim 8, wherein, in a ternary diagram of (sp3:sp2:H) representing a ratio [%] of a crystal structure of hydrocarbon, the ratio of the carbon-containing film is enclosed within a quadrangle ABCD formed by four points:
point A (sp3:sp2:H)=(80:0:20),
point B (sp3:sp2:H)=(0:80:20),
point C (sp3:sp2:H)=(0:50:50), and
point D (sp3:sp2:H)=(50:0:50).

10. The etching method according to claim 1, wherein the carbon-containing film has a thickness of 5 nm or more.

11. The etching method according to claim 10, wherein the thickness of the carbon-containing film is 10 nm or more and 100 nm or less.

12. The etching method according to claim 1, wherein the electrostatic chuck has a plurality of protrusions on the surface thereof, and
the carbon-containing film is formed at least on an upper surface of each of the plurality of protrusions.

13. The etching method according to claim 12, wherein the thickness of the carbon-containing film is thinner than a height of each of the plurality of protrusions.

14. The etching method according to claim 1, wherein (a) further includes forming an insulating film on the surface of the electrostatic chuck before (a1), and
the carbon-containing film is formed on the insulating film.

15. The etching method according to claim 1, wherein the electrostatic chuck includes:
a ceramic member;
at least one electrode arranged in the ceramic member; and
an insulating film on a surface of the ceramic member,
the insulating film is made of a material different from the ceramic member, and
the carbon-containing film is formed on the insulating film.

16. The etching method according to claim 14, further comprising:
(d) removing the carbon-containing film; and
(e) repeating a sequence including (a) to (d).

17. The etching method according to claim 16, wherein the insulating film contains silicon or carbon.

18. The etching method according to claim 1, further comprising removing the carbon-containing film after performing a cycle including (b) and (c) one or more times.

19. The etching method according to claim 18, wherein in the removing the carbon-containing film, the carbon-containing film is removed by plasma generated from an oxygen-containing gas.

20. An etching method comprising:
(a) forming an insulating film on a surface of an electrostatic chuck in a chamber;
(b) forming a carbon-containing film on the insulating film;
(c) repeating a first sequence until a first condition is satisfied, the first sequence including:
(c1) introducing a substrate into the chamber and disposing the substrate on the carbon-containing film;
(c2) etching the substrate with plasma; and
(c3) separating the substrate from the carbon-containing film and unloading the substrate from the chamber;
(d) removing the carbon-containing film after (c); and
(e) repeating a second sequence including (b) to (d) until a second condition is satisfied.

21. A pre-coat method comprising:
supplying a precoat gas containing carbon and hydrogen into a chamber and controlling a pressure in the chamber to be 100 mTorr or more and 1,000 mTorr or less; and
generating plasma from the precoat gas, thereby forming a pre-coat film on a surface of an electrostatic chuck disposed in the chamber.

22. An etching apparatus comprising:
a chamber including at least one gas supply port and at least one gas discharge port;
an electrostatic chuck disposed in the chamber;
a plasma generator; and
circuitry,
wherein the circuitry is configured to control the etching apparatus to execute a process including:
(a) forming a carbon-containing film on the electrostatic chuck;
(b) disposing a substrate on the carbon-containing film; and
(c) etching the substrate with plasma, and
wherein (a) includes:
(a1) supplying a precoat gas containing carbon and hydrogen into the chamber and controlling a pressure in the chamber to be 100 mTorr or more and 1,000 mTorr or less; and
(a2) generating the plasma from the precoat gas.
